(19) United States
(12) Patent Application Publication
(10) Pub. No.: US 2025/0364463 A1
(43) Pub. Date: Nov. 27, 2025

(54) ELECTRONIC DIE ASSEMBLY COMPRISING BONDING PADS DIRECTLY CONNECTED TO CONDUCTIVE TRACKS

(71) Applicant: COMMISSARIAT A L'ENERGIE ATOMIQUE ET AUX ENERGIES ALTERNATIVES, PARIS (FR)

(72) Inventors: Pablo RENAUD, GRENOBLE CEDEX 09 (FR); Jean CHARBONNIER, GRENOBLE CEDEX 09 (FR); Christophe DUBARRY, GRENOBLE CEDEX 09 (FR)

(21) Appl. No.: 19/214,572

(22) Filed: May 21, 2025

(30) Foreign Application Priority Data
May 21, 2024 (FR) FR2405168

(51) Int. Cl. H01L 23/00; H01L 23/528

(52) U.S. Cl. CPC H01L 24/08; H01L 23/528; H01L 24/06; H01L 24/80; H01L 2224/06177; H01L 2224/08145; H01L 2224/80895

(57) ABSTRACT

An electronic die assembly includes a first die and a second die superimposed on and electrically and mechanically connected to each other, the first die including a first interconnection structure and the second die including a second interconnection structure, the first interconnection structure and the second interconnection structure each including superimposed interconnection levels; first bonding pads disposed on the first interconnection structure; and second bonding pads disposed on the second interconnection structure, the second bonding pads being bonded to the first bonding pads; in which assembly: the last interconnection level of the first die comprises first conductive tracks; at least part of the first bonding pads are directly connected to the first conductive tracks; and a solid matter-free gap separates the last interconnection level of the first die from the second die and extends between at least part of the first conductive tracks.

### CROSS-REFERENCE TO RELATED APPLICATIONS

This application claims priority to French Patent Application No. 2405168, filed May 21, 2024, the entire content of which is incorporated herein by reference in its entirety.

### FIELD

The technical field of the invention is that of three-dimensional electronic die assemblies. The invention more particularly relates to an assembly comprising two electronic dies and bonding pads for electrically connecting the two dies. The assembly is designed to reduce heat transfer between the two dies, crosstalk and electrical losses.

### BACKGROUND

Three-dimensional (3D) integration consists in stacking several electronic dies (also referred to as integrated circuits) and electrically connecting them, for example using a bonding technique. This approach especially makes it possible to reduce overall size of so-called “heterogeneous” systems which are comprised of circuits belonging to different generations of a same semiconductor device technology or circuits belonging to different technologies, for example an image sensor comprising an array of photodiodes and a CMOS image processing circuit comprising logic circuits. 3D integration also makes it possible to increase the density of transistors per unit area without reducing their dimensions, to reduce power consumption and/or to increase the operating speed of a system, by replacing long horizontal interconnections with short vertical interconnections.

There are several 3D stacking architectures, especially as a function of the way the dies are stacked, the orientation of the dies and the type of bonding.

Stacking can be made according to different approaches: wafer-to-wafer, die-to-wafer or even die-to-die. The wafer-to-wafer technique is the fastest in terms of the number of dies bonded per hour, because it is collective bonding on the scale of silicon wafers. It is also the most accurate for a given bonding speed. On the other hand, unlike the other two techniques, does not offer the option of assembling only so-called “Known Good Dies”, selected after a series of tests and cutting of the wafers. The die-to-die stacking technique naturally takes the longest to implement, as the dies are bonded together two by two after the wafers have been cut.

When the dies (or wafers) are oriented in the same sense, the front face of one die is bonded to the back face of another die (this assembly method is referred to as “face-to-back”). Conversely, when the dies (or wafers) are assembled after one of them has been turned over, the dies are bonded face-to-face or back-to-back.

Paper [“Hybrid bonding for 3D stacked image sensors: impact of pitch shrinkage on interconnect robustness”; J. Jourdon et al., 2018 IEEE International Electron Devices Meeting (IEDM), pp. 7.3.1-7.1.4, 2018] describes an example of a 3D stack comprising two electronic dies assembled face-to-face by hybrid bonding (Cu/SiO₂). The upper die is a BackSide Illuminated (BSI) image sensor and the lower die is an image processing logic circuit manufactured using CMOS technology. The two dies are assembled using copper interconnection pads surrounded by silicon dioxide. The interconnection pads (also referred to as HBM (Hybrid Metal Bonding) pads) have a repeat pitch between 1.44 μm and 8.8 μm.

In some applications, it is sought to limit heat transfer between the electronic dies of the stack as much as possible. Typically, when a first die is intended to operate at a very low temperature, it is necessary to limit heat transfer as much as possible between this first die and a second die that dissipates heat or is subjected to a different temperature, without compromising electrical conduction between the two dies.

By way of example, there can be mentioned quantum computing dies designed to operate at temperatures close to absolute zero (typically below 1.5 K) and to contain quantum bits, commonly referred to as qubits, whose state is highly sensitive to temperature. Such a quantum die is generally disposed in a dilution cryostat and can be electrically coupled to a CMOS technology reading and control circuit, also disposed inside the cryostat. This reading and control circuit, commonly referred to as “cryo-CMOS”, is designed to release as little heat as possible, but should nevertheless be thermally decoupled from the quantum die so as not to impair its operation.

Electronic die assemblies obtained by hybrid metal/dielectric bonding (such as Cu/SiO₂) are not the best adapted for these very low temperature applications, because the dielectric material is responsible for thermal leaks between the dies. The dielectric material is furthermore responsible for electrical losses which can be significant depending on the dielectric permittivity of the material (that of SiO₂, for example, is relatively low).

One solution for providing excellent electrical conduction while limiting heat conduction between two dies is to use one or more superconducting materials to make the interconnection between the two dies. Indeed, there are two main mechanisms for heat conduction at low temperatures. Firstly, heat is transferred by free electrons from one material to another. This phenomenon therefore only occurs in electrically conductive materials. On the other hand, heat is also transferred by vibrations of the lattice of atoms, in other words phonons, of the material or materials making up the interconnection. In a superconducting material brought at a temperature below its critical temperature Tc (i.e. the superconducting-conducting phase transition temperature), in other words in the superconducting state, free electrons condense into Cooper pairs. These Cooper pairs have the feature of not conducting heat. Using one or more superconducting materials to make the interconnection therefore makes it possible to reduce heat conduction by free electrons. However, when the interconnection temperature is close to the critical temperature Tc, residual electrons that have not formed Cooper pairs continue to conduct heat.

For a given superconducting material, the lower the temperature, the more electrons organise themselves into Cooper pairs in the material and therefore the lower the thermal conduction by the residual free electrons. To significantly reduce thermal conduction by free electrons, it is generally considered necessary to reach a temperature T of less than Tc/10.

By way of example, paper [“Nb—Nb direct bonding at room temperature for superconducting interconnects”, M. Fujino et al, Journal of Applied Physics 133, 015301, 2023] describes the assembly of two silicon substrates by direct bonding of superconducting interconnection pads of niobium. The superconducting interconnection pads, formed on the surface of each of the substrates, have a diameter of 200 μm and a repeat pitch of 650 μm.

The use of superconducting interconnection pads is a solution for reducing thermal conduction in a die assembly operating at very low temperature, but it does not provide any improvement in die assemblies operating at room temperature. Additionally, it has no influence on electrical losses or crosstalk, which are two important parameters especially for RF applications.

### SUMMARY

There is a need to limit thermal conduction, electrical losses and crosstalk in a microchip assembly, regardless of the operating temperature of the assembly.

According to one aspect of the invention, this need tends to be satisfied by providing an electronic die assembly comprising:
a first die and a second die superimposed on and electrically and mechanically connected to each other, the first die comprising:
   a first substrate;
   a first interconnection structure disposed on the first substrate and comprising a plurality of superimposed interconnection levels;
the second die comprising:
   a second substrate;
   a second interconnection structure disposed on the second substrate and comprising a plurality of superimposed interconnection levels;
a plurality of first bonding pads disposed on the first interconnection structure; and
a plurality of second bonding pads disposed on the second interconnection structure, the second bonding pads being bonded to the first bonding pads.

Furthermore, in this assembly,
the interconnection level of the first die furthest from the first substrate, called the last interconnection level of the first die, comprises first conductive tracks which extend in parallel to a plane of the first substrate;
at least part of the first bonding pads are directly connected to the first conductive tracks; and
a solid matter-free gap separates the last interconnection level of the first die from the second die and extends between at least part of the first conductive tracks.

The solid matter-free, and more particularly of dielectric material-free, gap reduces thermal conduction between the dies, crosstalk and dielectric losses. The direct connection between the first bonding pads and the first conductive tracks simplifies manufacture of the assembly and reduces electrical resistance of the interconnections between the two dies, compared with a connection by means of conductive vias. Joule effect losses in the assembly are therefore decreased.

In an embodiment, the first conductive tracks of said at least part have stripped side walls, at least over part of their height.

In an embodiment of the assembly:
the interconnection level of the second die furthest from the second substrate, called the last interconnection level of the second die, comprises second conductive tracks which extend in parallel to a plane of the second substrate;
at least part of the second bonding pads are directly connected to the second conductive tracks; and
the solid matter-free gap further extends between at least part of the second conductive tracks.

According to one development of this embodiment, the second conductive tracks of said at least part have stripped side walls, at least over part of their height.

Further to the characteristics just discussed in the preceding paragraph, the electronic die assembly according to the first aspect of the invention may have one or more complementary characteristics from among the following, considered individually or according to any technically possible combinations:
the first bonding pads have in a first direction a first repeat pitch and the second bonding pads have in the first direction a second repeat pitch equal to the first repeat pitch;
the first repeat pitch is less than or equal to 10 μm, such as between 1 μm and 7 μm;
the first bonding pads have a third repeat pitch in a second direction intersecting the first direction and the second bonding pads have in the second direction a fourth repeat pitch equal to the third repeat pitch;
the third repeat pitch is less than or equal to 10 μm, such as between 1 μm and 7 μm;
the third repeat pitch is equal to the first repeat pitch;
the first bonding pads and the second bonding pads are superconducting;
the first die is a quantum circuit and the second die is a circuit for reading and controlling the quantum circuit;
the first die is an infrared bolometric sensor and the second die is a multiplexing circuit or a circuit for reading the infrared bolometric sensor; and
the first die and the second die are radiofrequency circuits.

A second aspect of the invention relates to a method for manufacturing an electronic die assembly comprising a first die and a second die superimposed on and electrically and mechanically connected to each other, the first die comprising
a first substrate;
a first interconnection structure disposed on the first substrate and comprising a plurality of superimposed interconnection levels;
   the second die comprising:
a second substrate;
a second interconnection structure disposed on the second substrate and comprising a plurality of superimposed interconnection levels.

The method comprises the following steps of:
forming a plurality of first bonding pads on the first interconnection structure, the interconnection level of the first die furthest from the first substrate, called the last interconnection level of the first die, comprising first conductive tracks which extend in parallel to a plane of the first substrate and a first dielectric layer lining the first conductive tracks, at least part of the first bonding pads being directly connected to the first conductive tracks;
etching the first dielectric layer between at least part of the first conductive tracks;
forming a plurality of second bonding pads on the second interconnection structure;
assembling the first die and the second die by bonding the first bonding pads to the second bonding pads, so that a solid matter-free gap separates the last interconnection level of the first die from the second die and extends between said at least part of the first conductive tracks.

In an embodiment, the first bonding pads are bonded to the second bonding pads by a direct bonding technique, beneficially by direct hydrophilic bonding.

In a mode of implementation, forming the first bonding pads comprises the following sub-steps of:
forming a conductive layer on the last interconnection level of the first die;
polishing the conductive layer so as to achieve a surface roughness of less than 0.5 nm;
forming an etch mask on the conductive layer;
etching the conductive layer through the etch mask; and
removing the etch mask.

According to one development of this mode of implementation, the first dielectric layer is etched prior to removing the etch mask.

According to a second development compatible with the first one, forming the first bonding pads further comprises:
prior to forming the conductive layer, depositing a barrier layer onto the last interconnection level of the first die; and
after etching the conductive layer, etching the barrier layer.

According to a third development compatible with the first and second developments, the method further comprises the following steps of:
between polishing the conductive layer and forming the etch mask, depositing a protective layer onto the conductive layer;
prior to etching the conductive layer, etching the protective layer through the etch mask to expose the conductive layer; and
after removing the etch mask, removing the protective layer.

### BRIEF DESCRIPTION OF THE FIGURES

Further characteristics and benefits of the invention will become more apparent from the description thereof given below, by way of indicating and in no way limiting purposes, with reference to the appended figures, in which:

FIG. 1 represents a cross-section view of an embodiment of a die assembly according to the first aspect of the invention;

FIG. 2 represents a top view of the bonding pads on one of the dies in the assembly of FIG. 1;

FIGS. 3A-3E, 4A-4E and 5 represent steps of a manufacturing method for assembling electronic dies according to the second aspect of the invention.

For greater clarity, identical or similar elements are identified by identical reference signs throughout the figures.

### DETAILED DESCRIPTION

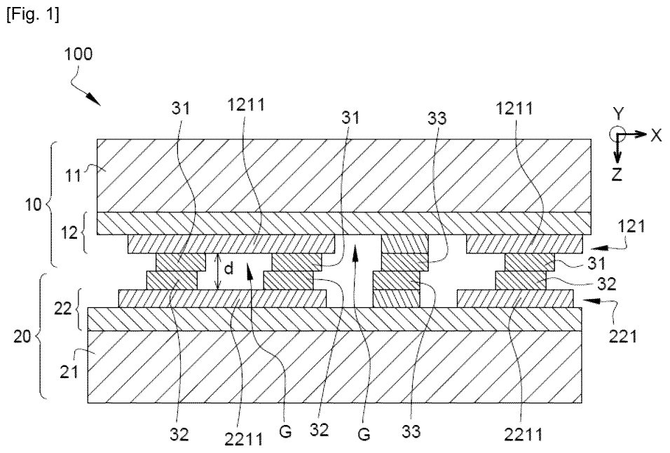

FIG. 1 is a schematic partial cross-section view of a microchip assembly 100 according to an embodiment of the invention. The electronic die assembly 100, referred to hereinafter simply as “assembly 100”, comprises at least two electronic dies: a first die 10 and a second die 20. By “electronic die”, it is meant an electronic component based on a semiconductor material, fulfilling one or more electronic functions and integrating several electronic components in a reduced volume. The expression “integrated circuit” will be considered as a synonym for electronic die.

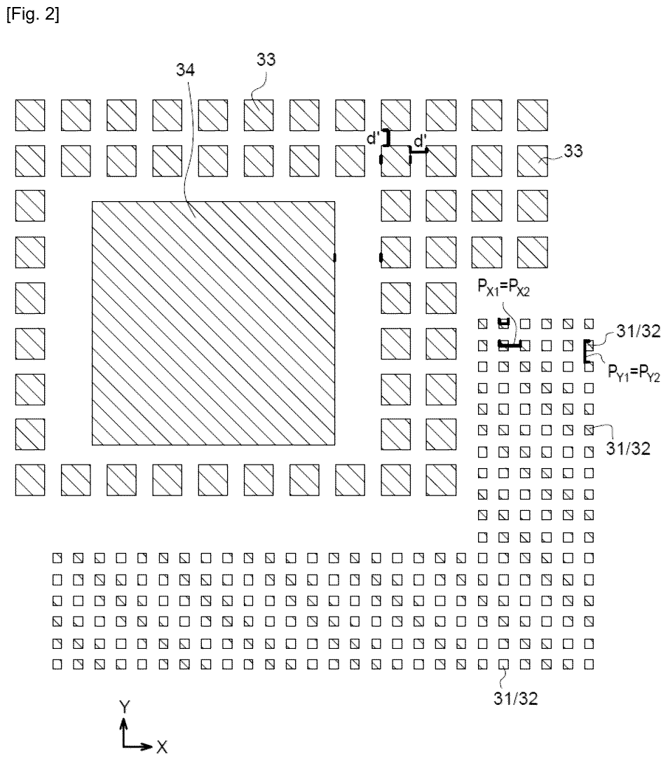

The first die 10 and the second die 20 are superimposed, in other words disposed one on top of the other. As such, assembly 100 can also be designated by the term “die stack”. In the orientation of FIG. 2, the first die 10, referred to as the upper die, is disposed above the second die 20, referred to as the lower die. Furthermore, the first die 10 and the second die 20 are electrically and mechanically connected to each other.

The assembly 100 may be designed to operate at very low temperature, i.e. at a temperature less than or equal to 1.5 K, typically less than or equal to 100 mK. It is designed to limit heat transfer between dies 10 and 20 in order to avoid, for example, heat released by one of the dies propagating to the other die and preventing it from operating (at very low temperature) or impairing its performance. Assembly 100 has especially beneficial applications in the fields of quantum computing, superconducting electronics and space.

By way of example, the first die 10 is a quantum circuit, i.e. a circuit designed to contain quantum bits or qubits, and the second die is a circuit for reading and controlling the quantum circuit, for example in CMOS technology. To be brought to a very low temperature, the assembly 100 can be disposed in a dilution cryostat.

According to another example, the first die 10 is an infrared bolometric sensor (for example for space observation) and the second die 20 is a circuit for reading the infrared bolometric sensor or a multiplexing circuit.

Alternatively, assembly 100 can be designed to operate at higher temperatures, for example at room temperature, for applications in which thermal conduction between the dies is less of a problem. It especially finds beneficial applications in the field of radiofrequencies (RF). Indeed, it is also designed to limit electrical losses, more particularly Joule effect losses and dielectric losses, as well as the phenomenon of crosstalk between dies and within a same die.

In this way, the first die 10 and the second die 20 can be RF circuits, i.e. circuits operating with signals at frequencies between 3 kHz and 300 GHz.

The first die 10 comprises a first substrate 11 and a first interconnection structure 12 disposed on the first substrate 11. The first substrate 11 comprises an active layer of a semiconductor material, such as silicon. It contains electronic components or devices (not represented), such as transistors, photodiodes, memory cells, quantum devices, bolometers, etc. These electronic devices are at least in partly formed in the semiconductor active layer. The first substrate 11 extends in a plane XY.

The first interconnection structure 12 comprises a plurality of superimposed interconnection levels 121, also referred to as routing levels. The interconnection levels 121 are superimposed along a direction Z perpendicular to the plane XY of the substrate. The interconnection levels 121 can connect the electronic devices of the first die 10 electrically to each other.

For the sake of clarity, only one interconnection level 121, furthest from the first substrate 11, is represented in FIG. 1. This interconnection level 121 is referred to as “level N”, N being the total number of interconnection levels 121 in the first interconnection structure 12 (N≥2), or even “last interconnection level” (their numbering, from 1 to N, being commonly achieved starting from the substrate).

Likewise, the second die 20 comprises a second substrate 21 and a second interconnection structure 22 disposed on the second substrate 21. The second substrate 21 contains electronic devices (transistors, photodiodes, memory cells, quantum devices, etc.), at least partly formed in a semiconductor active layer (the semiconductor material may be different from that of the first substrate). The second substrate 21 extends in a plane parallel to the plane XY of the first substrate 11.

Just like the first interconnection structure 12, the second interconnection structure 22 comprises a plurality of interconnection levels 221 superimposed (in the direction Z). The interconnection levels 221 can connect the electronic devices of the second die 20 electrically to each other. Again, only the last interconnection level 221 of the second interconnection structure 22, furthest from the second substrate 21, is represented in FIG. 1.

An interconnection level 121, 221 may be a so-called “line” level (generally designated by “M1”, “M2”, “M3” . . . ) or a so-called “via” level (“V1”, “V2”, “V3” . . . ). A line level comprises a plurality of conductive lines or tracks which extend in parallel to the plane XY of the first substrate 11, whereas a via level comprises conductive vias which extend perpendicularly to the plane XY of the first substrate 11, i.e. along the direction Z. In a plane parallel to the plane XY, the cross-sectional area of the conductive vias is smaller than that of the conductive tracks. The conductive tracks and conductive vias are typically formed of one metal or several stacked metals. Two consecutive levels of lines are beneficially separated and electrically connected by a via level. A conductive via (in a via level) therefore connects two conductive tracks belonging to different levels.

Further to the conductive tracks and conductive vias, an interconnection level 121, 221 may comprise a dielectric layer lining the conductive tracks or conductive vias, as well as one or more interface layers such as a metal diffusion barrier layer, a hard mask layer or a polishing stop layer. The interconnection levels 121, 221 are obtained by virtue of the method known as “Damascene”, for example.

The electronic devices of a same die belong to a first functional block (or set of technological levels) referred to as “Front End Of Line” or FEOL, while the interconnection levels 121, 221 of a same die belong to a second functional block referred to as “Back End Of Line” or BEOL.

Further to the first and second dies 10, 20, the assembly 100 comprises first bonding pads 31 disposed on the first interconnection structure 12 and second bonding pads 32 disposed on the second interconnection structure 22. The first bonding pads 31 belong to a first bonding level superimposed on the last interconnection level 121 of the first interconnection structure 12, while the second bonding pads 32 belong to a second bonding level superimposed on the last interconnection level 221 of the second interconnection structure 22.

The first bonding pads 31 (hereinafter referred to as “first pads 31”) and the second bonding pads 32 (hereinafter referred to as “second pads 32”) may also be referred to as “first interconnection pads” and “second interconnection pads” respectively, insofar as they electrically and mechanically interconnect both dies.

The first pads 31 may be identical in shape and dimensions (within manufacturing tolerances). The second pads 32 may also be identical in shape and dimensions. The shape and dimensions of the second pads 32 may be different from those of the first pads 31.

In a plane parallel to the plane XY of the first substrate 11, the first and second pads 31-32 can have a rectangular (for example square), round or hexagonal cross-section, etc. Their dimensions in this same plane can be between 100 nm and 1 mm, such as between 100 nm and 7 μm, and for example between 1 μm and 5 μm.

Each of the first pads 31 is bonded to a second pad 32, and conversely, each of the second pads 32 is bonded to a first pad 31. In other words, the first and second pads 31-32 are connected in pairs. The first and second pads 31-32 provide electrical and mechanical connection between both dies.

Beneficially, the dies 10 and 20 are interconnected to each other by means of the first and second pads 31-32 by a direct bonding technique, i.e. without introducing any intermediate compound (such as an adhesive, a wax or a low melting point alloy) at the bonding interface, and for example by direct hydrophilic bonding. In this way, the interconnections between dies 10 and 20 are free of intermediate compounds, especially solder material. Each interconnection may consist of a first pad 31 and a second pad 32.

The first pads 31 are electrically connected to the first interconnection structure 12. Thus they are electrically connected to the electronic devices of the first die 10.

More particularly, the last interconnection level 121 of the first die 10 comprises first conductive tracks 1211 and at least part of the first pads 31 are directly connected to the first conductive tracks 1211. By “directly connected”, it is meant that the first pads 31 are in direct contact with the first conductive tracks 1211, and not connected via a conductive via as is the case in conventional die assemblies. A first conductive track 1211 may be connected to one or more first pads 31 (which are therefore electrically connected by the first track).

In an embodiment, each of the first pads 31 is directly connected to a first conductive track 1211.

The fact that the assembly 100 is free of conductive via between the first pads 31 and the last interconnection level 121 of the first die 10 (in other words that the first bonding level is free of conductive via) simplifies manufacturing of the assembly 100, as the manufacturing method does not then include the steps relating to forming these vias. Furthermore, the electrical resistance between the two dies in the assembly is decreased. Indeed, conductive vias have a higher electrical resistance than conductive tracks due to their smaller cross-sectional area and the fact that they generally include a metal diffusion barrier layer.

Furthermore, in the assembly 100, a gap G separates the last interconnection level 121 of the first die 10 and the last interconnection level 221 of the second die 20. This gap G also separates the pairs of first and second pads 31-32 from each other. This gap G is free of solid matter, especially dielectric material. It may contain a gas or a mixture of gases, for example air.

The gap G constitutes an inter-die cavity into which the first pads 31 and the second pads 32 extend. This inter-die cavity is in an embodiment open onto the external environment. Thus, when using assembly 100, for example in a dilution cryostat, the pressure of the gas or gas mixture in gap G can be decreased until a given vacuum level is achieved.

The material-free gap G improves thermal insulation between dies 10 and 20 (by limiting the thermal transport of phonons between the dies), compared to two dies separated by an underfill material or by an oxide (as in the case of Cu/SiO₂ hybrid bonding, for example). Furthermore, gap G limits crosstalk between RF signals propagating in the two dies. By “RF signals”, it is meant signals with a frequency between 3 kHz and 300 GHz. As gap G further separates the first pads 31 from each other and the second pads 32 from each other, it also limits crosstalk between RF signals propagating in different interconnections. Finally, because there is no dielectric material between the bonding pads, dielectric losses are also decreased.

The distance d between the last interconnection level 121 of the first die 10 and the last interconnection level 221 of the second die 20 is beneficially between 100 nm and 2 μm. It is measured perpendicularly to the plane XY of the first substrate 11 (along Z).

Another feature of the assembly 100 is that the solid matter-free gap G further extends between at least part of the first conductive tracks 1211 of the last interconnection level 121 of the first die 10, and for example between each pair of first conductive tracks 1211. This contributes to further decreasing crosstalk and dielectric losses.

Beneficially, the first conductive tracks 1211 of said at least part have stripped side walls, at least over part of their height (measured along Z) and for example over their entire height. The height of the first conductive tracks 1211 is, for example, between 10 nm and 2 μm.

In an embodiment, the gap G surrounds the first pads 31, the second pads 32 and the first conductive tracks 1211.

In the embodiment of the assembly 100 represented by FIG. 1, what has just been described for the first die 10 applies mutatis mutandis to the second die 20. Thus, the last interconnection level 221 of the second die 20 comprises second conductive tracks 2211 and at least part of the second pads 32 are directly connected to the second conductive tracks 2211. In an embodiment, each second pad 32 is directly connected to a second conductive track 2211.

Additionally, gap G extends between at least part of the second conductive tracks 2211, and in an embodiment between all the second conductive tracks 2211. Beneficially, the second conductive tracks 2211 of said at least part have stripped side walls, at least over part of their height and for example over their entire height. The height of the second conductive tracks 2211 is, for example, between 10 nm and 2 μm.

Manufacturing time for assembly 100, electrical resistance (absence of conductive vias between second pads 32 and second conductive tracks 2211), crosstalk and dielectric losses (absence of dielectric material between second conductive tracks 2211) are even more decreased.

The first pads 31 may have, in a first direction X of the plane XY, a first repeat pitch P_{X1} less than or equal to 10 μm, and for example between 1 μm and 7 μm. The second pads 32 then have, in the same direction X, a second repeat pitch P_{X2} equal to the first repeat pitch P_{X1}.

Such repeat pitches ensure excellent mechanical strength between dies 10 and 20 and enable a high density of interconnections between the dies, compatible with some high integration density applications. These repeat pitches are especially compatible with the need to scale up quantum circuits. Indeed, quantum circuits are designed to contain a very large number of qubits, which have to be connected individually to the reading and control circuit. The number of interconnections required between dies is therefore very high, in particular in quantum circuits with spin qubits in silicon.

The first and second pads 31-32 consist of one or more electrically conductive materials, for example selected from titanium (Ti), aluminium (Al), gold (Au), copper (Cu), platinum (Pt), niobium (Nb), niobium-titanium (NbTi), niobium-germanium (NbsGe), niobium nitride (NbN), niobium alumina (NbsAl), tantalum (Ta), tantalum nitride (TaN), titanium nitride (TiN), vanadium (V) and vanadium silicide (V₃Si). The first pads 31 and/or the second pads 31-32 may be formed of an alloy of at least two of these materials. They may also comprise several stacked conductive layers formed of different materials.

The use of one or more superconducting materials to form pads 31-32 reduces thermal conduction by electrons between dies 10 and 20 when used at very low temperatures. Fully superconducting interconnections are furthermore of particular interest when the first die 10 is a quantum circuit with superconducting qubits, as they make it possible to retain the phase and amplitude properties of the signal when moving from one die to another.

The first pads 31 can consist of one and the same superconducting material (for example selected from the above materials and alloys thereof). Likewise, the second pads 32 can consist of one and the same superconducting material, for example identical to that of the first pads 31. The first and second pads 31-32 are for example of niobium.

Alternatively, the first pads 31 and/or the second pads 32 each comprise a stack of a first superconducting layer and a second superconducting layer. The first superconducting layer is formed of a first superconducting material, for example TiN, and the second superconducting layer is formed of a second superconducting material different from the first superconducting material, for example niobium. The first superconducting layer is the one in contact with the die 10, 20, so when the first and second pads 31-32 all comprise stacks, bonding takes place between the second superconducting layers.

The first superconducting material and the second superconducting material can be selected so as to form an acoustic mismatch interface (also referred to as a Kapitza interface). Such an interface allows part of the phonons to be reflected and therefore reduces thermal conductivity of the interconnections by phonons. Indeed, an interface thermal resistance is created at the interface between the first and second superconducting layers. The greater the difference in the sound velocity between the two superconducting materials, the greater this interface thermal resistance. This velocity difference results in a very effective reflection of phonons at the interface, which is why the term “phonon mirror” is also employed.

Examples of superconducting material pairs to create an acoustic mismatch interface are described in patent applications FR3125359A1 and FR2984602A1.

According to another alternative, the first pads 31 and the second pads 32 each comprise a stack of alternating several first superconducting layers and several second superconducting layers, in order to form a multitude of acoustic mismatch interfaces (for example more than 10 interfaces) and thus drastically reduce thermal conduction by phonons between both dies. The greater the number of interfaces, the more effective the phonon mirror.

FIG. 2 represents an example of layout of the first pads 31 on the first interconnection structure 12 of the first die 10 or of the second pads 32 on the second interconnection structure 22 of the second die 20. The first and second pads 31-32 herein have a square cross-section.

As is represented, the first pads 31 may have a third repeat pitch P_{Y1} in a second direction Y intersecting the first direction X and the second pads 32 may have in the second direction Y a fourth repeat pitch P_{Y2} equal to the third repeat pitch P_{Y1}. In this way, the first and second pads 31-32 are arranged in a regular array, or matrix, comprising rows and columns. The second direction Y is in an embodiment perpendicular to the first direction X. The third repeat pitch P_{Y1} is beneficially less than or equal to 10 μm, for example between 1 μm and 7 μm. It may be equal to the first repeat pitch P_{X1}. The first or second pads 31, 32 then form a square mesh network.

The first and second pads 31-32 are functional pads in that they are connected to the electronic devices on the dies 10, 20 by the interconnection structures 12, 22. Beneficially, they are contained in a so-called active zone on the surface of the dies 10, 20.

Further to these functional pads, the assembly 100 may include other pads on the interconnection structure 12, 22 of each of the dies 10, 20, especially non-functional bonding pads 33, also referred to as “dummies”. These non-functional pads are used exclusively for bonding two dies together (see also FIG. 1). In other words, they are mechanical only (and not electrical) connection pads. They are connected to neither the electronic devices on dies 10, 20, nor the interconnection structures 12, 22.

The non-functional pads 33 are beneficially placed to avoid having large pad-free areas, typically greater than 100×100 μm², beneficially greater than 20×20 μm². For example, they have the shape of squares with sides of 2 μm to 100 μm and are spaced two by two by a distance d′ between 2 μm and 50 μm.

Finally, the assembly 100 may comprise, on the interconnection structure 12, 22 of each of the dies 10, 20, one or more test pads 34 for verifying proper operation of the dies before they are bonded (see FIG. 2). These test pads 34 participate in bonding in the same way as the first and second pads 31-32 and the non-functional pads 33. These test pads 34 have typically much larger dimensions than the functional pads 31-32 and the non-functional pads 33.

The non-functional pads 33 and the test pads 34 on each die are beneficially formed of the same material or materials as the first or second pads 31, 32.

The (bonding) surface area of the bonding pads, all types combined (first/second pads, non-functional pads and test pads), is in an embodiment greater than 25%, such as greater than 40%, of the surface area of the first face 10a, 20a.

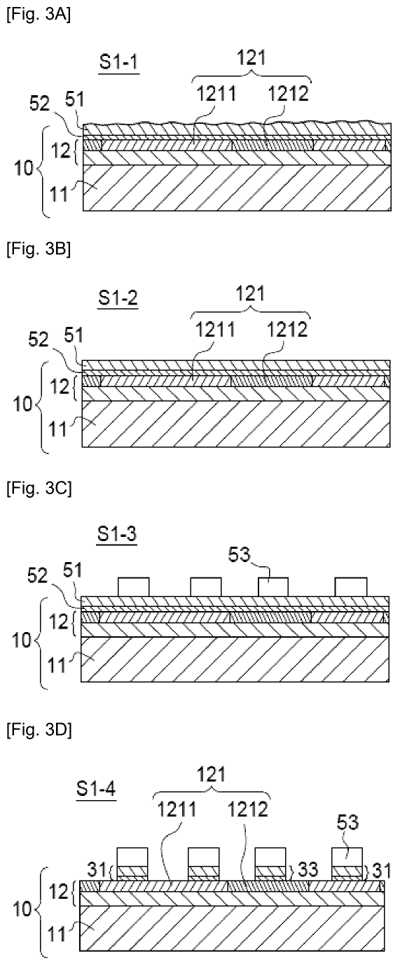

FIGS. 3A to 3E, 4A to 4E and 5 schematically represent steps S1 to S5 of a method for manufacturing the die assembly 100.

The manufacturing method especially comprises a step S1 of forming the first pads 31 on the first interconnection structure 12 of the first die 10 and a step S3 of forming the second pads 32 on the second interconnection structure 22 of the second die 20.

According to a mode of implementation, step S1 of forming the first pads 31 comprises several sub-steps S1-1 to S1-4 represented by FIGS. 3A to 3D.

The first die 10 is provided with a last interconnection level 121 comprising a first dielectric layer 1212 which lines the first conductive traces 1211. The first conductive tracks 1211 are flush with the surface of the first dielectric layer 1212. The last interconnection level 121 may have a thickness (equal to the thickness of the first dielectric layer 1212 and the first conductive tracks 1211) between 10 nm and 2 μm, such as between 100 nm and 1 μm. It may have a low topography (<1 μm) and a flatness compatible with direct bonding techniques.

Sub-step S1-1 in FIG. 3A comprises forming a conductive layer 51 on the last interconnection level 121 of the first die 10. The thickness of the conductive layer 51 may be between 100 nm and 10 μm, for example equal to 200 nm or 400 nm.

The conductive layer 51 may comprise a number of sub-layers of different conductive materials, in particular different superconducting materials, in order to form one or more acoustic mismatch interfaces, as previously described.

Sub-step S1-1 may also comprise depositing a barrier layer 52 prior to forming the conductive layer 51. The barrier layer 52 enables the conductive layer 51 to better adhere to the surface of the first die 10 and to protect the conductive layer 51 from oxidation, by forming a barrier to the diffusion of oxidising species. It is formed of an electrically conductive, beneficially superconductive, material, for example titanium nitride (TIN). Titanium nitride is highly appropriate for a (super) conductive layer 51 comprising niobium (Nb NbTi, Nb₃Ge, NbN, Nb₃Al, etc.). The thickness of the barrier layer 52 can be between 5 nm and 200 nm, for example 20 nm.

The conductive layer 51 is in electrical contact with the first conductive tracks 1211 (which open onto the surface of the first die 10), via the barrier layer 52 if necessary, in order to connect the future first pads 31 directly to the first conductive tracks 1211.

Sub-step S1-2 in FIG. 3B consists in polishing the conductive layer 51 so as to achieve a surface roughness compatible with direct bonding, typically less than 0.5 nm, such as less than 0.2 nm. These roughness values are expressed as root mean square values. The root mean square roughness (noted Rq) is determined by statistical analysis of an atomic force microscope image, taking a surface area of 1×1 μm² as sample.

This polishing sub-step S1-2 can be carried out by Chemical Mechanical Polishing (CMP).

The polished conductive layer 51 is then structured to form the first pads 31. This structuring is herein carried out in two sub-steps S1-3 and S1-4 illustrated by FIGS. 3C and 3D.

In S1-3 (see FIG. 3C), an etch mask 53 is formed on the conductive layer 51. The etch mask 53 may be a resin mask or a hard mask. Its formation especially comprises a photolithography step. The etch mask 53 comprises first patterns (formed by solid parts of the mask) whose shape and dimensions correspond to those of the first pads 31 to be formed. The etch mask 53 may also include other patterns corresponding to the other bonding pads on the dies (non-functional pads 33 and test pads 34).

Then, in sub-step S1-4 (see FIG. 3D), the conductive layer 51, and the barrier layer 52 if necessary, are etched through the etch mask 53, thus obtaining the first pads 31 (and, if necessary, the non-functional pads 33 and test pads 34).

Herein, each first pad 31 comprises a portion of the conductive layer 51 and a portion of the barrier layer 52.

The conductive layer 51 and the barrier layer 52 are in an embodiment etched by Reactive Ion Etching (RIE).

Etching of the barrier layer 52 can be carried out immediately after etching of the conductive layer 51 and in the same etching frame, for example using the same chemistry.

Finally, the etch mask 53 is removed after etching sub-step S1-4.

Beneficially, the manufacturing method further comprises, between polishing the conductive layer 51 (sub-step S1-2) and forming the etch mask 53 (sub-step S1-3), depositing a protective layer onto the conductive layer 51. This protective layer, also referred to as an encapsulation layer, protects the conductive layer 51 from forming the etch mask 53, etching the conductive layer 51 and removing the etch mask 53, so that the first pads 31 have an upper face without impairments (e.g. oxidation), defects or residues. The protective layer is, for example, of silicon dioxide (SiO₂), silicon nitride (SiN) or titanium (Ti). Its thickness is in an embodiment between 5 nm and 2 μm in the case of SiO₂ or SiN and between 5 nm and 500 nm in the case of titanium.

Between forming the etch mask 53 (sub-step S1-3) and etching the conductive layer 51 (sub-step S1-4), the protective layer is etched through the etch mask 53 to expose the conductive layer 51 (so-called protective layer opening sub-step). The protective layer is removed after removing the etch mask 53, such as by wet etching, for example in a dilute hydrofluoric acid (HF) solution.

With reference to FIG. 3E, the manufacturing method comprises a step S2 of etching the first dielectric layer 1212 between at least part of the first conductive tracks 1211. This etching aims at forming part of the solid material-free gap G between said conductive tracks 1211.

Beneficially, the first dielectric layer 1212 is etched selectively relative to the first conductive tracks 1211 (and the first pads 31) so as to strip all the conductive tracks 1211, at least over part of their height, and for example over their entire height. The first dielectric layer 1212 is in an embodiment etched by reactive ion etching (RIE).

The step S2 of etching the first dielectric layer 1212 can be carried out before or after removing the etch mask 53, however it is desirable that it is carried out before (and therefore prior to removing the protective layer, if necessary) so that the upper face of the first pads 31 is not exposed to this etching.

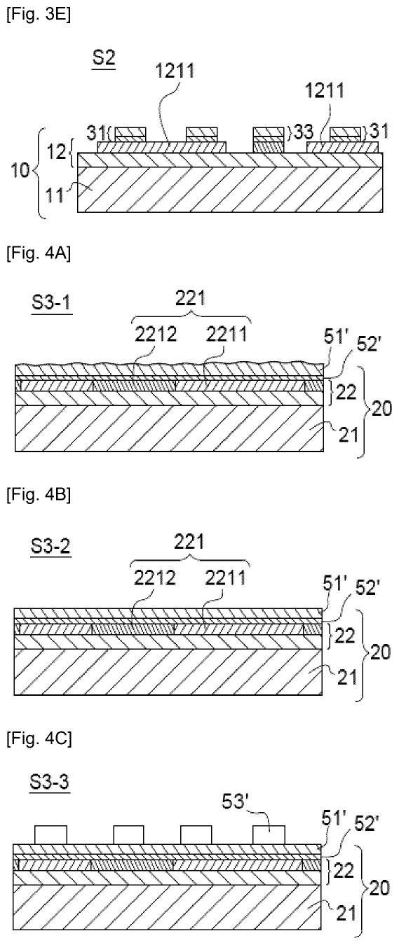

Forming the second pads 32 on the second interconnection structure 22 of the second die 20 can be accomplished in the same way as forming the first pads 31. Thus, the above description of step S1 applies mutatis mutandis to step S3 which especially comprises the sub-steps S3-1, S3-2, S3-3 and S3-4 illustrated respectively by FIG. 4A, FIG. 4B, FIG. 4C and FIG. 4D. A second barrier layer 52′ beneficially, a second conductive layer 51′, a second protective layer (beneficially) and a second hard mask 53′ will thus be formed.

The second pads 32 are beneficially formed so as to be directly connected to the second conductive tracks 2211 of the last interconnection level 221. The second conductive tracks 2211 are lined with a second dielectric layer 2212, in the same way as the conductive tracks 1211 are lined with the first dielectric layer 1212. Just like the last interconnection level 121 of the first die 10, the last interconnection level 221 of the second die 20 can have a thickness between 10 nm and 2 μm, such as between 100 nm and 1 μm. It may have a low topography (<1 μm) and a flatness compatible with direct bonding techniques.

In order to also strip the second conductive tracks 2211 (to further reduce crosstalk and dielectric losses in the assembly), the manufacturing method may include, with reference to FIG. 4E, a step S4 of etching the second dielectric layer 2212 between at least part of the second conductive tracks 2211. This step S4 may be performed in the same way as step S3 of FIG. 3E.

At the end of steps S2 and S3 (or S4), the first pads 31 project from the surface of the first die 10 (formed by the first interconnection structure 12) and the second pads 32 project from the surface of the second die 20 (formed by the second interconnection structure 22).

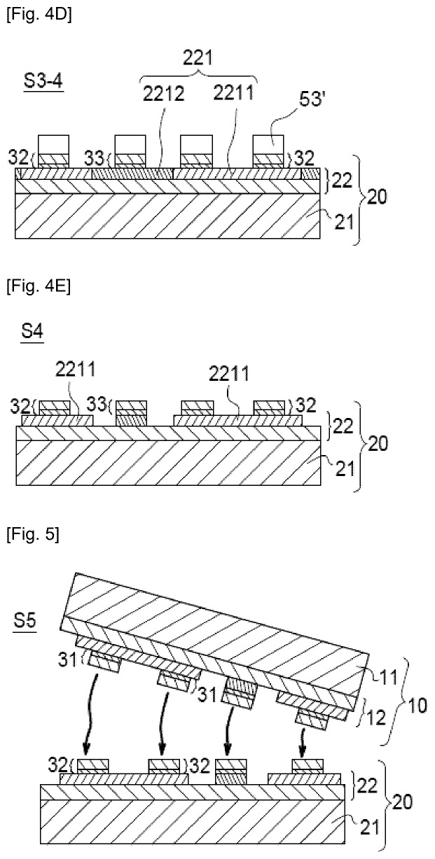

Step S5 of FIG. 5 consists in assembling the first and second dies 10, 20 by bonding the first pads 31 to the second pads 32, resulting in assembly 100. This bonding is carried out after flipping one of the two dies 10, 20, herein the first die 10 (referred to as flip-chip bonding).

In this mode of implementation, the bonding technique employed is a direct bonding technique, for example hydrophilic direct bonding or Surface Activated Bonding (SAB).

Hydrophilic direct bonding, or hydrophilic molecular adhesion bonding, is a bonding technique that implements hydrophilic bonding surfaces (which is the case of the upper faces of the first and second pads 31-32) and whose principle is based on the spontaneous adhesion of surfaces by virtue of van der Waals forces (including hydrogen bonds and capillary bridges). It is simpler and quicker to implement than Surface-Activated Bonding (SAB), as it can be carried out at room temperature and under atmospheric pressure, unlike surface-activated bonding (SAB) which is made under ultra-high vacuum. Aligning the first pads 31 with the second pads 32 is also easier than with SAB. It can be performed in a hybrid bonding machine conventionally used for 3D applications. Additionally, there is no need to apply a compressive force between the two dies, as this type of bonding is spontaneous.

Additionally, hydrophilic direct bonding brings about very few defects at the bond interface, such as voids. Furthermore, it does not produce an interface layer typically comprising implanted argon atoms (as may be the case with SAB).

However, hydrophilic direct bonding can optionally be made under vacuum, with a vacuum level between 10⁻² Pa and 1000 Pa (10⁻⁴ mbar and 10 mbar), which is much easier and cheaper to achieve than ultra-high vacuum (10⁻⁶-10⁻¹⁰ Pa, corresponding to 10⁻⁸-10⁻¹² mbar).

After bonding, the manufacturing method can also include a step of annealing the assembly 100 at a low temperature, in order to further create metallic bonds between the bonding pads and thus enhance hold between the dies. The annealing temperature is low enough not to damage the electronic devices on the dies. It can be between 100° C. and 400° C., such as between 100° C. and 350° C., and for example between 100° C. and 300° C. This annealing step is optional, as the adhesion strength of the dies bonded by direct adhesion is already high.

Also optionally, one of the two substrates 11 and 21 can also be thinned by grinding and/or (dry or wet) etching.

Steps S1 to S5 (plus possible annealing) of the manufacturing method are beneficially implemented on a wafer scale. As such, the first die belongs to a first wafer and the second die belongs to a second wafer. The die assembly 100 is then individualised by cutting the assembly of the two wafers.

The first plate may comprise several copies of the first die 10 and the second plate may comprise several copies of the second die 20, in order to obtain several copies of the assembly 100.

Direct hydrophilic bonding between two wafers does not generally require the application of force to the back faces of the wafers. It may, however, be useful to apply pressure after or during the bonding operation in order to contact all the pads. This is useful if one or both of the wafers have significant deflection (typically between 100 μm and 500 μm).

After bonding, the wafer assembly may undergo further manufacturing steps, some involving one or more fluids (gas, liquid or plasma). In order to prevent the penetration of fluid into the gap G between the dies 10 and 20, which could damage the dies, the bonding pads or adversely affect the bonding quality, a peripheral sealing ring can be formed in the zone between the plates. This sealing ring can comprise two parts, one on the surface of the first plate and the other on the surface of the second plate. In an embodiment, the first part of the sealing ring is formed at the same time as the first pads 31 (by etching the first conductive layer 51, previously fully deposited on the wafer) and the second part of the sealing ring is formed at the same time as the second pads 32 (by etching the second conductive layer 51′, previously fully deposited on the wafer). The first and second parts of the ring are brought into contact during bonding step S5.

Alternatively, a peripheral sealing ring can be provided for each die assembly (forming a half-ring on each die), and not at the wafer assembly, to facilitate degassing during annealing and thus avoid stresses due to pressure.

The peripheral sealing ring can be between 10 μm and 2 mm wide, as a function of the number and nature of the technological steps to be carried out after bonding.

In one alternative implementation, only steps S1 to S4 of the manufacturing method are implemented at wafer scale. The bonding step S5 is implemented according to the die-to-plate or die-to-die approach, in other words after the first die has been cut out and/or the second die has been cut out.

The electronic die assembly and its manufacturing method are not limited to the embodiments described above.

In particular, the solid matter-free gap G may not extend between second conductive tracks 2211 of the second die 20 (by not etching the second dielectric layer 2212 of the last interconnection level 221).

Additionally, the second interconnection structure 22 of the second die 20 may have thereabove a bonding level comprising the second pads 32 and conductive vias connecting the second pads 32 to the second interconnection structure 22 (and more particularly to the last interconnection level 221). The conductive vias are lined with dielectric material, as well as the second conductive tracks 2211.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

The articles “a” and “an” may be employed in connection with various elements, components, compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

As used herein in the specification and in the claims, the phrase “at least one”, in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

A person skilled in the art will readily appreciate that various features, elements, parameters disclosed in the description may be modified and that various embodiments disclosed may be combined without departing from the scope of the invention. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Having described above several aspects of at least one embodiment, it is to be appreciated various alterations, modifications, and improvements will readily occur to those skilled in the art. Such alterations, modifications, and improvements are intended to be aspects of this disclosure. Accordingly, the foregoing description and drawings are by way of example only.

The invention claimed is:

1. An electronic die assembly comprising:
a first die and a second die superimposed on and electrically and mechanically connected to each other, the first die comprising
a first substrate;
a first interconnection structure disposed on the first substrate and comprising a plurality of superimposed interconnection levels;
the second die comprising:
a second substrate;
a second interconnection structure disposed on the second substrate and comprising a plurality of superimposed interconnection levels;
a plurality of first bonding pads disposed on the first interconnection structure; and
a plurality of second bonding pads disposed on the second interconnection structure, the second bonding pads being bonded to the first bonding pads;
in which assembly:
the interconnection level of the first die furthest from the first substrate, called the last interconnection level of the first die, comprises first conductive tracks which extend in parallel to a plane of the first substrate;
at least part of the first bonding pads are directly connected to the first conductive tracks; and
a solid matter-free gap separates the last interconnection level of the first die from the second die and extends between at least part of the first conductive tracks.

2. The assembly according to claim 1, wherein the first conductive tracks of said at least part have stripped side walls, at least over part of their height.

3. The assembly according to claim 1, wherein:
the interconnection level of the second die furthest from the second substrate, called the last interconnection level of the second die, comprises second conductive tracks which extend in parallel to a plane of the second substrate;
at least part of the second bonding pads are directly connected to the second conductive tracks; and
the solid matter-free gap further extends between at least part of the second conductive tracks.

4. The assembly according to claim 3, wherein the second conductive tracks of said at least part have stripped side walls, at least over part of their height.

5. The assembly according to claim 1, wherein the first bonding pads have in a first direction a first repeat pitch and wherein the second bonding pads have in the first direction a second repeat pitch equal to the first repeat pitch.

6. The assembly according to claim 5, wherein the first repeat pitch is less than or equal to 10 μm.

7. The assembly according to claim 5, wherein the first bonding pads have a third repeat pitch in a second direction intersecting the first direction and wherein the second bonding pads have in the second direction a fourth repeat pitch equal to the third repeat pitch.

8. The assembly according to claim 1, wherein the first bonding pads and the second bonding pads are superconducting.

9. The assembly according to claim 1, wherein the first die is a quantum circuit and the second die is a circuit for reading and controlling the quantum circuit.

10. The assembly according to claim 1, wherein the first die is an infrared bolometric sensor and the second die is a multiplexing circuit or a circuit for reading the infrared bolometric sensor.

11. The assembly according to claim 1, wherein the first die and the second die are radiofrequency circuits.

12. A method for manufacturing an electronic die assembly comprising a first die and a second die superposed on and electrically and mechanically connected to each other, the first die comprising
a first substrate;
a first interconnection structure disposed on the first substrate and comprising a plurality of superimposed interconnection levels;
the second die comprising:
a second substrate;
a second interconnection structure disposed on the second substrate and comprising a plurality of superimposed interconnection levels;
which method comprises:
forming a plurality of first bonding pads on the first interconnection structure, the interconnection level of the first die furthest from the first substrate, called the last interconnection level of the first die, comprising first conductive tracks which extend in parallel to a plane of the first substrate and a first dielectric layer lining the first conductive tracks, at least part of the first bonding pads being directly connected to the first conductive tracks;
etching the first dielectric layer between at least part of the first conductive tracks;
forming a plurality of second bonding pads on the second interconnection structure;
assembling the first die and the second die by bonding the first bonding pads to the second bonding pads, so that a solid matter-free gap separates the last interconnection level of the first die from the second die and extends between said at least part of the first conductive tracks.

13. The method according to claim 12, wherein the first bonding pads are bonded to the second bonding pads by a direct bonding technique.

14. The method according to claim 13, wherein the direct bonding technique is hydrophilic direct bonding.

15. The method according to claim 12, wherein forming the first bonding pads comprises:
forming a conductive layer on the last interconnection level of the first die;
polishing the conductive layer to achieve a surface roughness of less than 0.5 nm;
forming an etch mask on the conductive layer;
etching the conductive layer through the etch mask; and
removing the etch mask.

16. The method according to claim 14, wherein the first dielectric layer is etched prior to removing the etch mask.

17. The method according to claim 14, wherein forming the first bonding pads further comprises:
prior to forming the conductive layer, depositing a barrier layer onto the last interconnection level of the first die; and
after etching the conductive layer, etching the barrier layer.

18. The method according to claim 14, further comprising:
between polishing the conductive layer and forming the etch mask, depositing a protective layer onto the conductive layer;
prior to etching the conductive layer, etching the protective layer through the etch mask to expose the conductive layer; and
after removing the etch mask, removing the protective layer.
